(19) United States
(12) Patent Application Publication
(10) Pub. No.: US 2025/0264956 A1
(43) Pub. Date: Aug. 21, 2025

(54) DISPLAY DEVICE

(71) Applicant: LG Display Co., Ltd., Seoul (KR)

(72) Inventors: Ruda RHE, Paju-si (KR); JiHyun JUNG, Paju-si (KR); SuChang AN, Paju-si (KR); JaeGyun LEE, Paju-si (KR); Hyangmyoung GWON, Paju-si (KR)

(21) Appl. No.: 18/968,946

(22) Filed: Dec. 4, 2024

(30) Foreign Application Priority Data
Feb. 20, 2024 (KR) 10-2024-0024076

(51) Int. Cl. G06F 3/041; G06F 3/044; G09G 3/3233; H10K 59/121; H10K 59/40

(52) U.S. Cl. CPC G06F 3/04164; G06F 3/0412; H10K 59/40; G06F 3/0446; G06F 2203/04111; G09G 3/3233; G09G 2300/0842; G09G 2354/00; H10K 59/1213

(57) ABSTRACT

Embodiments of the present disclosure relate to a display device. A display device may include a first touch routing line electrically connected to a first touch pad and including a resistance compensation pattern, and a second touch routing line electrically connected to a second touch pad, thereby reducing a resistance difference between the touch routing lines.

### CROSS-REFERENCE TO RELATED APPLICATION

This application claims priority from Korean Patent Application No. 10-2024-0024076, filed on Feb. 20, 2024, which is hereby incorporated by reference for all purposes as if fully set forth herein.

### BACKGROUND

### Technical Field

Embodiments of the present disclosure relate to a display device.

### Description of the Related Art

As the information society develops, there is increasing the demand for display devices for displaying images in various forms. Therefore, in recent years, there have been used various display devices such as liquid crystal displays and organic light emitting display devices.

A display device may include touch sensors, and the display device may recognize a touch operation of a user.

### BRIEF SUMMARY

Embodiments of the present disclosure may provide a display device capable of reducing the resistance difference between touch routing lines.

Embodiments of the present disclosure may provide a display device capable of reducing the variation in signal transmission speed between touch routing lines.

Embodiments of the present disclosure may provide a display device capable of low power due to reduced deviation in signal transmission speed.

Embodiments of the present disclosure may provide a display device including a substrate including a display area, a first pad area, and a second pad area, a first touch pad disposed in the first pad area, a second touch pad disposed in the second pad area, which is an area of an edge of the substrate, a first touch routing line electrically connected to the first touch pad, and including a resistance compensation pattern, and a second touch routing line electrically connected to the second touch pad.

The resistance compensation pattern of the first touch routing line may have a zigzag shape.

The display device according to embodiments of the present disclosure ma further include a gate metal disposed on the substrate, and disposed in the first pad area and a jumping area between the first pad area and the display area, a metal pattern overlapping with at least a portion of the gate metal, a first source-drain electrode pattern disposed on the gate metal and the metal pattern, and electrically connected to the gate metal and the metal pattern in the jumping area, a second source-drain electrode pattern disposed on the first source-drain electrode pattern, and electrically connected to the first source-drain electrode pattern, and a touch sensor metal disposed on the second source-drain electrode pattern, and electrically connected to the second source-drain electrode pattern. In this case, the first touch routing line may include at least one of the gate metal, the metal pattern, the first source-drain electrode pattern, the second source-drain electrode pattern, or the touch sensor metal.

The gate metal of the first touch routing line and the metal pattern of the first touch routing line may include the resistance compensation pattern.

The resistance compensation pattern formed on the gate metal may be disposed to overlap with at least a portion of the resistance compensation pattern formed on the metal pattern.

The resistance compensation pattern formed on the gate metal may have a different shape from the resistance compensation pattern formed on the metal pattern.

According to embodiments of the present disclosure, it is possible to provide a display device capable of reducing the resistance difference between touch routing lines.

According to embodiments of the present disclosure, it is possible to provide a display device capable of reducing the variation in signal transmission speed between touch routing lines.

According to embodiments of the present disclosure, it is possible to provide a display device capable of low power due to reduced deviation in signal transmission speed.

### BRIEF DESCRIPTION OF THE SEVERAL VIEWS OF THE DRAWINGS

FIG. 1 is a system configuration diagram of a display device according to embodiments of the present disclosure.

FIG. 2 illustrates a display panel according to embodiments of the present disclosure.

FIG. 3 illustrates a substrate of a display panel according to embodiments of the present disclosure.

FIG. 4 is a cross-sectional view of a display area of a display panel according to embodiments of the present disclosure.

FIGS. 5 and 6 illustrate configurations for touch sensing according to embodiments of the present disclosure.

FIGS. 7 and 8 are cross-sectional views of a display panel including a touch routing line and a touch pad according to embodiments of the present disclosure.

FIG. 9 is a plan view of a touch routing line and a touch pad according to embodiments of the present disclosure.

FIG. 10 is a plan view of a touch routing line and a touch pad according to embodiments of the present disclosure.

FIG. 11 is a plan view of a touch routing line and a touch pad according to embodiments of the present disclosure.

FIGS. 12 and 13 illustrate the resistance compensation patterns according to embodiments of the present disclosure.

FIG. 14 is a plan view of a touch routing line and a touch pad according to embodiments of the present disclosure.

FIGS. 15, 16, and 17 are cross-sectional views of touch pads and a second touch routing line disposed in a first pad area according to embodiments of the present disclosure.

FIG. 18 and FIG. 19 are cross-sectional views of a touch routing line and a touch pad according to embodiments of the present disclosure.

FIG. 20 is a plan view of a touch routing line and a touch pad according to embodiments of the present disclosure.

FIG. 21 is a plan view of a display panel in which a color filter is disposed on an encapsulation layer according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the disclosure are described in detail with reference to the accompanying drawings.

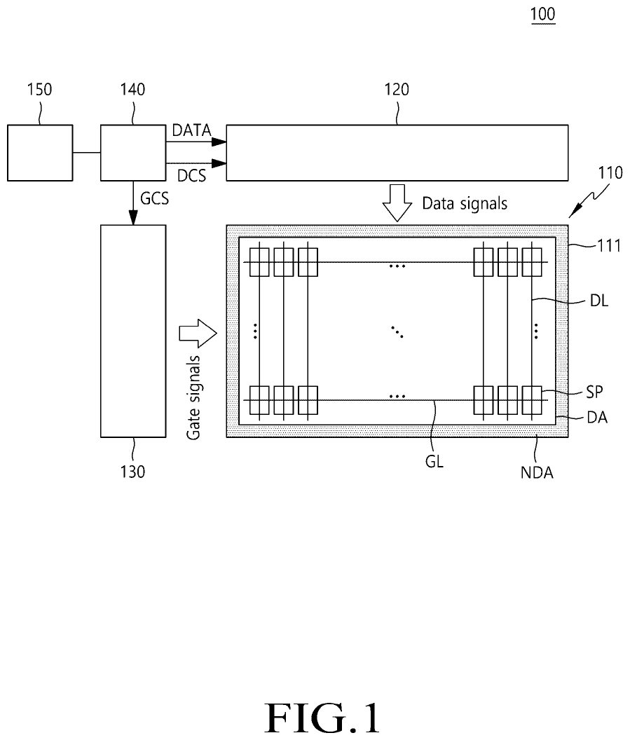

FIG. 1 is a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

A plurality of subpixels SP for image display may be disposed in the display area DA, and the non-display area NDA may include a pad area PA located in the first direction from the display area DA.

In a display panel 110 according to embodiments of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to embodiments of the present disclosure may be a liquid crystal display device or the like, or may be a self-luminous display device in which the display panel 110 emits light by itself. When the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology.

The display controller 140 may be mounted on a printed circuit board, a flexible printed circuit, etc., and may be electrically connected to the data driving circuit 120 and the gate driving circuit 130 through a printed circuit board, a flexible printed circuit.

In order to provide not only an image display function but also a touch sensing function, the display device 100 according to embodiments of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit may supply a touch driving signal to at least one of the pluralities of touch electrodes and generate touch sensing data by sensing at least one of the pluralities of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television of various sizes, but is not limited thereto, and may be a display of various types and sizes capable of displaying information or images.

The display device 100 according to embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

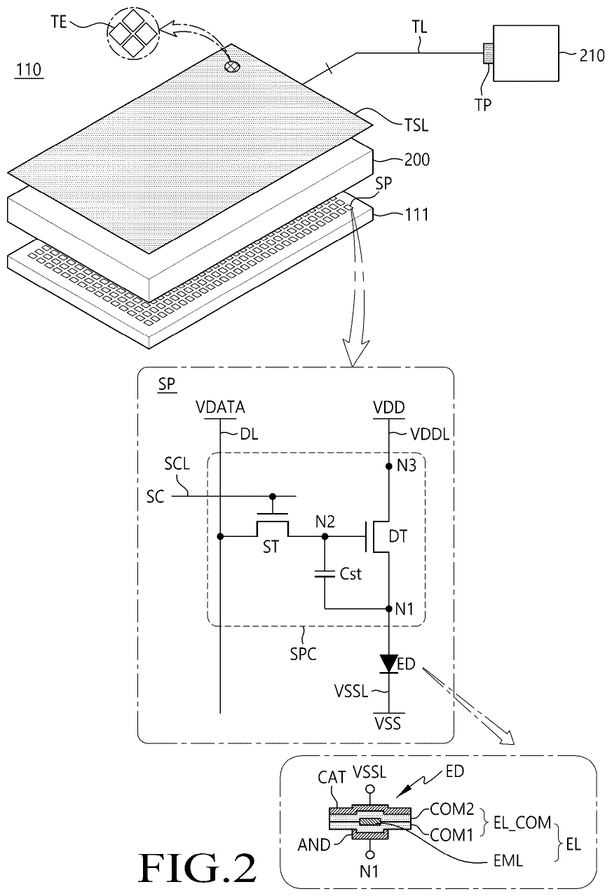

FIG. 2 illustrates a display panel 110 according to embodiments of the present disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP in order to drive the subpixel SP.

The light emitting device ED may include an anode AND, a light emitting device intermediate layer EL, and a cathode CAT. The light emitting device intermediate layer EL may be a layer disposed between the anode AND and the cathode CAT.

In the case that the light emitting device ED is an organic light emitting device, the light emitting device intermediate layer EL may include an emission layer EML, a first common intermediate layer COM1 between the anode AND and the emission layer EML, and a second common intermediate layer COM2 between the emission layer EML and the cathode. The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as a common intermediate layer EL_COM.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device intermediate layer EL and a cathode CAT. A predetermined emission area may be formed by each light emitting device ED. For example, the emission area of each light emitting device ED may include an area where the anode AND, the light emitting device intermediate layer EL and the cathode CAT overlap.

The driving transistor DT may be a driving transistor for supplying driving current to the light emitting device ED. The driving transistor DT may be connected between a first common driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, the subpixel circuit SPC may further include one or more transistors or one or more capacitors.

For example, the subpixel circuit SPC may have an 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

Referring to FIG. 2, the display device 100 according to the embodiments of the present disclosure may further include a touch sensor layer TSL including a plurality of sensor electrodes to sense a touch of a user, and a touch sensing circuit 210 configured to sense the plurality of sensor electrodes to determine the presence or absence of a touch or touch coordinates.

The touch sensor layer TSL may be built or embedded into the display panel 110. For example, the touch sensor layer TSL may be disposed on an encapsulation layer 200 within the display panel 110.

The display panel 110 may not only include the touch sensor layer TSL, but may also include a plurality of touch pads to which the touch sensing circuit 210 is electrically connected, and a plurality of touch routing lines TL for electrically connecting the plurality of sensor electrodes included in the touch sensor layer TSL and the plurality of touch pads connected to the touch sensing circuit 210.

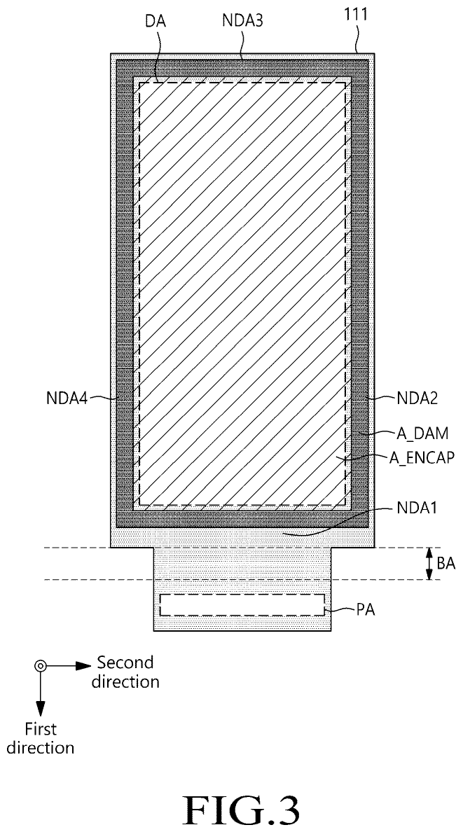

FIG. 3 illustrates a substrate 111 of a display panel 110 according to embodiments of the present disclosure.

Referring to FIG. 3, the substrate 111 of the display panel 110 according to the embodiments of the present disclosure may include a display area DA on which an image may be displayed and a non-display area NDA on which an image is not displayed.

Referring to FIG. 3, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction intersecting the first direction may be a row direction (e.g., X-axis direction).

Referring to FIG. 3, the first non-display area NDA1 may include a pad area PA in which a plurality of pads is disposed.

In the pad area PA, there may be disposed a plurality of pads to which a driving circuit is electrically connected. A plurality of driving circuits or printed circuit boards may be electrically connected. For example, the plurality of pads may include a plurality of display pads and a plurality of touch pads. A plurality of data lines, a first common driving voltage line VDDL, and a second common driving voltage line VSSL may be electrically connected to the plurality of display pads. A plurality of touch routing lines TL may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include a bending area BA.

Referring to FIG. 3, the display panel 110 may further include a ground line disposed in a non-display area NDA of the substrate 111. The ground line may be disposed from one point of the pad area PA to another point of the pad area PA via the second non-display area NDA2, the third non-display area NDA3 and the fourth non-display area NDA4.

Referring to FIG. 3, the display panel 110 may include an encapsulation layer area A_ENCAP and a dam area A_DAM.

Referring to FIG. 3, the encapsulation layer area A_ENCAP may be an area where the encapsulation layer 200 is disposed. In the display panel 110 according to the embodiments of the present disclosure, the encapsulation layer 200 may have a structure in which an inorganic film and an organic film are laminated. In this case, an edge of the encapsulation layer 200 may be considered as an edge of the organic film.

Referring to FIG. 3, the dam area A_DAM may be an area surrounding the encapsulation layer area A_ENCAP. A structure serving as a dam may be located in the dam area A_DAM. The dam may prevent the organic film in a liquid state from flowing out to the outside.

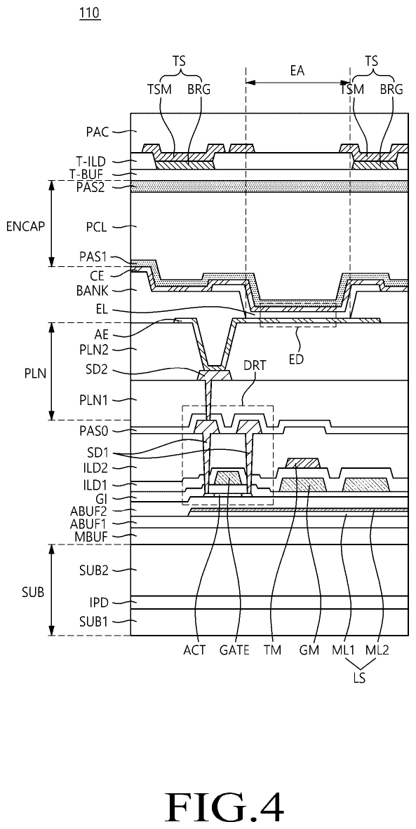

FIG. 4 is a cross-sectional view of the display area DA of the display panel 110 according to the embodiments of the present disclosure.

Referring to FIG. 4, the substrate SUB may include a first substrate SUB1, an interlayer insulating film IPD, and a second substrate SUB2. The interlayer insulating film IPD may be located between the first substrate SUB1 and the second substrate SUB2. The substrate SUB may be configured to include the first substrate SUB1, the interlayer insulating film IPD and the second substrate SUB2, thereby preventing moisture penetration. For example, the first substrate SUB1 and the second substrate SUB2 may be polyimide PI substrates. The first substrate SUB1 may be referred to as a primary PI substrate, and the second substrate SUB2 may be referred to as a secondary PI substrate.

Referring to FIG. 4, there may be disposed various patterns (e.g., ACT, SD1, GATE1), various insulating films or insulating layers (e.g., MBUF, ABUF1, ABUF2, GI, ILD1, ILD2, PAS0), and various metal patterns (e.g., TM, GM, ML1, ML2) for forming transistors such as driving transistors DRT on the substrate SUB.

Referring to FIG. 4, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be a light shielding layer LS capable of blocking the light.

A second active buffer layer ABUF2 may be disposed on the first metal layer ML1 and the second metal layer ML2. An active layer ACT of a driving transistor DRT may be disposed on the second active buffer layer ABUF2.

A gate insulating film GI may be disposed while covering the active layer ACT.

A gate electrode GATE of a driving transistor DRT may be disposed on the gate insulating film GI. In this case, a gate material layer GM may be disposed on the gate insulating film GI together with the first gate electrode GATE1 of the driving transistor DRT at a position different from the formation position of the driving transistor DRT.

A first interlayer insulating film ILD1 may be disposed while covering the gate electrode GATE and the gate metal GM. A metal pattern TM may be disposed on the first interlayer insulating film ILD1. The metal pattern TM may be located at a different location from the formation location of the driving transistor DRT. A second interlayer insulating film ILD2 may be disposed while covering the metal pattern TM on the first interlayer insulating film ILD1.

Two first source-drain electrode patterns SD1 may be disposed on the second interlayer insulating film ILD2. One of the two first source-drain electrode patterns SD1 may be a source node of the driving transistor DRT, and the other may be a drain node of the driving transistor DRT. The two first source-drain electrode patterns SD1 may be electrically connected to one side and the other side of the active layer ACT through the contact holes of the second interlayer insulating film ILD2, the first interlayer insulating film ILD1 and the gate insulating film GI.

A portion of the active layer ACT overlapping with the first gate electrode GATE1 may be a channel region. One of the two first source-drain electrode patterns SD1 may be connected to one side of the channel region in the active layer ACT, and the other of the two first source-drain electrode patterns SD1 may be connected to the other side of the channel region in the active layer ACT.

A passivation layer PAS0 may be disposed to cover the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (corresponding to the second node N2 of the driving transistor DRT in the subpixel SP of FIG. 3) through the contact hole of the first planarization layer PLN1.

A second planarization layer PLN2 may be disposed while covering the second source-drain electrode pattern SD2. A light emitting device ED may be disposed on the second planarization layer PLN2.

In a stacked structure of the light emitting device ED, an anode electrode AE may be disposed on the second planarization layer PLN2. The anode electrode AE may be electrically connected to the second source-drain electrode pattern SD2 through a contact hole of the second planarization layer PLN2.

A bank BANK may be disposed to cover a part of the anode electrode AE. A part of the bank BANK corresponding to an emission area EA of the subpixel SP may be opened.

A part of the anode electrode AE may be exposed to an opening (e.g., open portion) of the bank BANK. An emission layer EL may be located on a side of the bank BANK and in the opening (e.g., open portion) of the bank BANK. All or a part of the emission layer EL may be located between adjacent banks BANK.

In the opening of the bank BANK, the emission layer EL may be in contact with the anode electrode AE. A cathode electrode CE may be disposed on the emission layer EL.

A light emitting device ED may be formed by the anode electrode AE, the emission layer EL and the cathode electrode CE. The emission layer EL may include an organic film.

An encapsulation layer ENCAP may be disposed on the light emitting device ED.

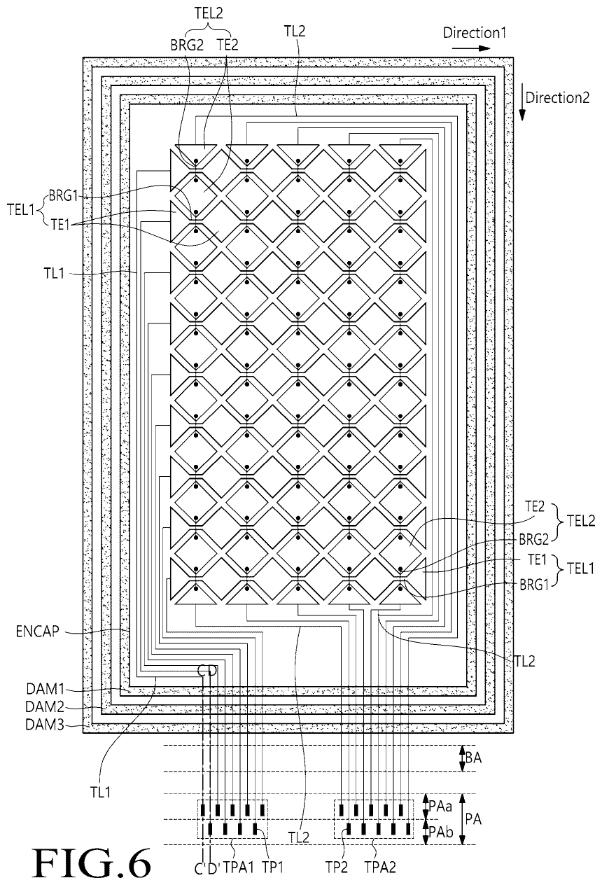

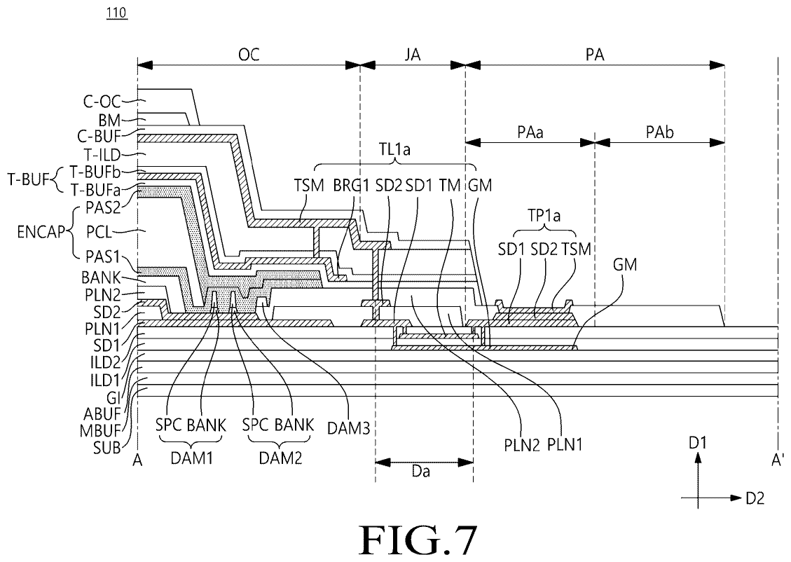

The encapsulation layer ENCAP may have a single-layer structure or a multi-layer structure. For example, as illustrated in FIGS. 6 and 7, the encapsulation layer ENCAP may include a first inorganic encapsulation layer PAS1, an organic encapsulation layer PCL and a second inorganic encapsulation layer PAS2.

For example, the first inorganic encapsulation layer PAS1 and the second inorganic encapsulation layer PAS2 may be inorganic films, and the organic encapsulation layer PCL may be an organic film. Among the first inorganic encapsulation layer PAS1, the organic encapsulation layer PCL, and the second inorganic encapsulation layer PAS2, the organic encapsulation layer PCL may be the thickest, and may act as a planarizing layer.

The first inorganic encapsulation layer PAS1 may be disposed on the cathode electrode CE, and may be disposed closest to the light emitting device ED. The first inorganic encapsulation layer PAS1 may be formed of an inorganic insulating material capable of low-temperature deposition. For example, the first inorganic encapsulation layer PAS1 may include silicon nitride (SiNx), silicon oxide (SiOx), silicon oxynitride (SiON), aluminum oxide (Al2O3), and the like. Since the first inorganic encapsulation layer PAS1 is deposited in a low-temperature atmosphere, the first inorganic encapsulation layer PAS1 may prevent the emission layer EL including an organic material vulnerable to a high-temperature atmosphere from being damaged during the deposition process.

The organic encapsulation layer PCL may be formed with a smaller area than the first inorganic encapsulation layer PAS1. In this case, the organic encapsulation layer PCL may be formed to expose both ends of the first inorganic encapsulation layer PAS1. The organic encapsulation layer PCL may act as a buffer to relieve stress between each layer due to the bending of the display device 100, and may also act to enhance the flattening performance. For example, the organic encapsulation layer PCL may be made of an acrylic resin, an epoxy resin, a polyimide, polyethylene, or a silicon oxycarbon SiOC, and may be formed of an organic insulating material. For example, the organic encapsulation layer PCL may be formed through an inkjet process.

The second inorganic encapsulation layer PAS2 may be formed on the substrate SUB on which the organic encapsulation layer PCL is formed, so as to cover the upper surface and side surface of each of the organic encapsulation layer PCL and the first inorganic encapsulation layer PAS1. The second inorganic encapsulation layer PAS2 may minimize or block external moisture or oxygen from penetrating into the first inorganic encapsulation layer PAS1 and the organic encapsulation layer PCL. For example, the second inorganic encapsulation layer PAS2 may be formed of an inorganic insulating material such as silicon nitride (SiNx), silicon oxide (SiOx), silicon oxynitride (SiON), or aluminum oxide (A(Al2O3).

Referring to FIG. 4, if the touch sensor TS is of a type built into the display panel PNL, the touch sensor TS may be disposed on the encapsulation layer ENCAP. The touch sensor structure will be described in detail as follows.

A touch buffer film T-BUF may be disposed on the encapsulation layer ENCAP. The touch sensor TS may be disposed on the touch buffer film T-BUF.

The touch sensor TS may include a touch sensor metal TSM and a bridge metal BRG located in different layers.

A touch interlayer insulating film T-ILD may be disposed between the touch sensor metal TSM and the bridge metal BRG.

For example, the touch sensor metal TSM may include a first touch sensor metal TSM, a second touch sensor metal TSM, and a third touch sensor metal TSM disposed adjacent to each other. If the third touch sensor metal TSM is located between the first touch sensor metal TSM and the second touch sensor metal TSM, and the first touch sensor metal TSM and the second touch sensor metal TSM are required to be electrically connected to each other, the first touch sensor metal TSM and the second touch sensor metal TSM may be electrically connected to each other through the bridge metal BRG located in a different layer. The bridge metal BRG may be insulated from the third touch sensor metal TSM by the touch interlayer insulating film T-ILD.

When the touch sensor TS is formed on the display panel PNL, there may be generated a chemical solution (e.g., developer solution or etchant, etc.) used in the process or moisture from the outside.

The touch buffer film T-BUF may be formed at a low temperature condition below a specific temperature (e.g., 100 degrees Celsius), and may be formed of an organic insulating material having a low permittivity of 1 to 3 in order to prevent damage to the emission layer EL containing an organic material which is vulnerable to high temperatures.

Referring to FIG. 4, a protective layer PAC may be disposed while covering a touch sensor TS. The protective layer PAC may be an organic insulating film. However, the protective layer PAC may be replaced with a color filter buffer layer (not shown). A color filter (not shown) and a black matrix (not shown) may be disposed on the color filter buffer layer (not shown). This may be called a CoE a color filter on encapsulation (CoE) structure.

The display device according to the embodiments of the present disclosure may sense a touch using a mutual-capacitance-based touch sensing method, or may sense a touch using a self-capacitance-based touch sensing method. However, Hereinafter, for the convenience of explanation, it will be described as an example in which the display device performs mutual-capacitance-based touch sensing and has a touch sensor structure therefor.

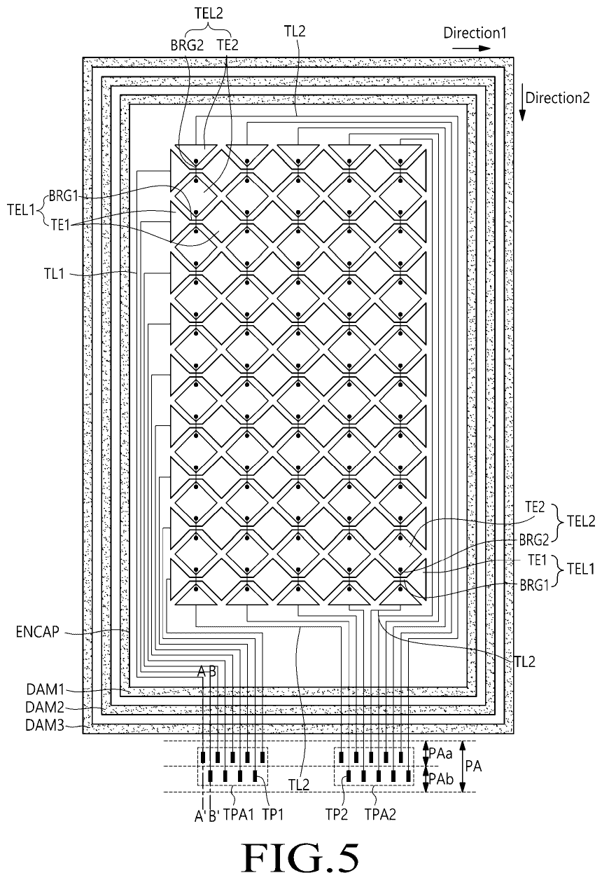

FIGS. 5 and 6 illustrate configurations for touch sensing according to embodiments of the present disclosure.

Referring to FIG. 5, a touch sensor structure for mutual-capacitance-based touch sensing may include a plurality of first touch electrode lines TEL1 and a plurality of second touch electrode lines TEL2. Here, the plurality of first touch electrode lines TEL1 and the plurality of second touch electrode lines TEL2 may be located on an encapsulation layer ENCAP.

Each of the plurality of first touch electrode lines TEL1 may be arranged in a first direction (e.g., Direction1), and each of the plurality of second touch electrode lines TEL2 may be arranged in a second direction (e.g., Direction2). The first direction and the second direction may be directions intersecting each other.

Referring to FIG. 5, each of the plurality of first touch electrode lines TEL1 may be formed of a plurality of first touch electrodes TE1 that are electrically connected. Each of the plurality of second touch electrode lines TEL2 may be composed of a plurality of second touch electrodes TE2 that are electrically connected. The plurality of first touch electrodes TE1 and the plurality of second touch electrodes TE2 may be included in a plurality of touch electrodes TE. The plurality of first touch electrodes TE1 constituting each of the plurality of first touch electrode lines TEL1 may be driving touch electrodes, and the plurality of second touch electrodes TE2 constituting each of the plurality of second touch electrode lines TEL2 may be sensing touch electrodes. In this case, each of the plurality of first touch electrode lines TEL1 may correspond to a driving touch electrode line, and each of the plurality of second touch electrode lines TEL2 may correspond to a sensing touch electrode line.

Referring to FIG. 5, a touch sensor metal for touch sensing may include a plurality of touch routing lines TL in addition to the plurality of first touch electrode lines TEL1 and the plurality of second touch electrode lines TEL2. The plurality of touch routing lines TL may include one or more first touch routing lines TL1 connected to each of the plurality of first touch electrode lines TEL1, and one or more second touch routing lines TL2 connected to each of the plurality of second touch electrode lines TEL2.

Referring to FIG. 5, each of the plurality of first touch electrode lines TEL1 may include a plurality of first touch electrodes TE1 arranged in the same row (or column), and one or more first bridge metals BRG1 electrically connecting the plurality of first touch electrodes TE1. Here, a first bridge metal BRG1 connecting two adjacent first touch electrodes TE1 may be a metal integrated with the two adjacent first touch electrodes TE1, or may be a metal connected to the two adjacent first touch electrodes TE1 through a contact hole.

Each of the plurality of second touch electrode lines TEL2 may include a plurality of second touch electrodes TE2 arranged in the same column (or row) and one or more second bridge metals BRG2 electrically connecting the plurality of second touch electrodes TE2. Here, the second bridge metal BRG2 connecting two adjacent second touch electrodes TE2 may be a metal integrated with the two adjacent second touch electrodes TE2, or may be a metal connected to two adjacent second touch electrodes TE2 through a contact hole.

Here, the first bridge metal BRG1 or the second bridge metal BRG2 connected to the first touch electrode TE1 or the second touch electrode TE2 through the contact hole may be referred to as a “connection pattern.”

In an area where the first touch electrode line TEL1 and the second touch electrode line TEL2 intersect (i.e., a touch electrode line intersection area), the first bridge metal BRG1 and the second bridge metal BRG2 may intersect.

Accordingly, in the touch electrode line intersection area, when the first bridge metal BRG1 and the second bridge metal BRG2 intersect, the first bridge metal BRG1 and the second bridge metal BRG2 may be disposed in different layers.

Therefore, in order for the plurality of first touch electrode lines TEL1 and the plurality of second touch electrode lines TEL2 to be disposed to intersect, the plurality of first touch electrodes TE1, the plurality of first bridge metals BRG1, the plurality of second touch electrodes TE2, the plurality of second touch electrode lines TEL2, and the plurality of second bridge metals BRG2 may be disposed in two or more layers.

Referring to FIG. 5, each of the plurality of first touch electrode lines TEL1 may be electrically connected to the corresponding first touch pad TP1 through one or more first touch routing lines TL1. That is, the first touch electrode TE1 disposed at the outermost side among the plurality of first touch electrodes TE1 included in one first touch electrode line TEL1 may be electrically connected to the corresponding first touch pad TP1 through the first touch routing line TL1.

Each of the plurality of second touch electrode lines TEL2 may be electrically connected to the corresponding second touch pad TP2 through one or more second touch routing lines TL2. That is, the second touch electrode TE2 disposed at the outermost side among the plurality of second touch electrodes TE2 included in one second touch electrode line TEL2 may be electrically connected to the corresponding second touch pad TP2 through the second touch routing line TL2.

Referring to FIG. 5, a pad area PA may include a plurality of touch pads TP1 and TP2.

Referring to FIG. 5, the plurality of touch pads TP1 and TP2 may be arranged in two rows. Referring to FIG. 5, the pad area PA where the plurality of touch pads TP1 and TP2 are disposed may include a first pad area PAa and a second pad area PAb. The touch pad disposed in the first pad area PAa may be referred to as a first row touch pad or a first row bump. The touch pad disposed in the second pad area PAb may be referred to as a second row touch pad or a second row bump. The first pad area PAa is between the display area DA and the second pad area PAb from a plan view. That is, the first pad area PAa is disposed closer to the display area DA than the second pad area PAb from a plan view.

The first pad area PAa may be an area closer to the display area DA than the second pad area PAb. The second pad area PAb may be located at an edge of a substrate (not shown).

Referring to FIG. 5, for example, the first touch pad TP1 may include nine pads, and the first touch pad TP1 may be disposed in a first touch pad area TPA1. Five pads of the first touch pad TP1 may be disposed in the first pad area PAa, which may be the first row touch pads of the first touch pad TP1. Four pads of the first touch pad TP1 may be arranged in the second pad area PAb, which may be the second row touch pads of the first touch pad TP1.

Referring to FIG. 5, for example, the second touch pad TP2 may include ten pads, and the second touch pad TP2 may be disposed in a second touch pad area TPA2. Five pads of the second touch pad TP2 may be disposed in the first pad area PAa, which may be the first row touch pads of the second touch pad TP2. Five pads of the second touch pad TP2 may be disposed in the second pad area PAb, which may be the second row touch pads of the second touch pad TP2.

Referring to FIG. 6, unlike as illustrated in FIG. 5, a bending area BA may be disposed between the pad area PA and the dams DAM1, DAM2 and DAM3.

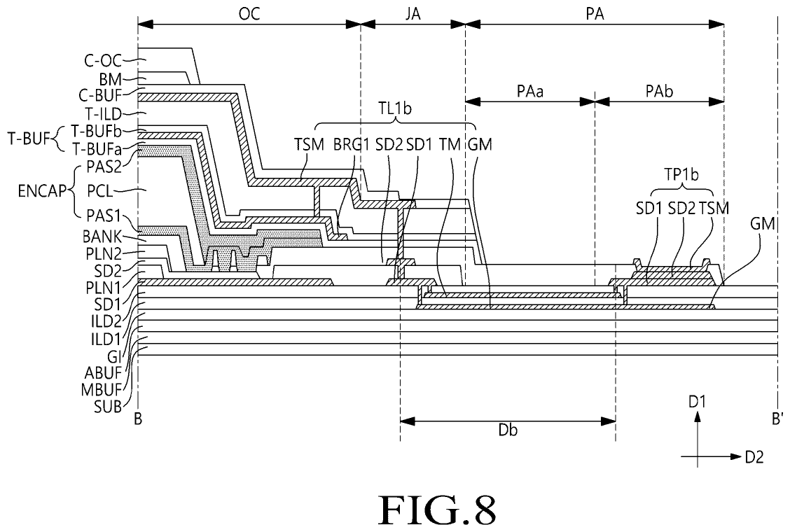

Referring to FIG. 5, a dam DAM may be disposed on the outside or periphery of the encapsulation layer ENCAP. The touch routing lines TL1 and TL2 may be electrically connected to the touch pads TP1 and TP2 through an area where the dam DAM is disposed. Referring to FIG. 5, there is illustrated the A-A′ area and the B-B′ area. Hereinafter, it will be described cross-sectional views of the A-A′ area and the B-B′ area with reference to FIGS. 7 and 8.

FIGS. 7 and 8 are cross-sectional views of a display panel including a touch routing line TL and a touch pad TP according to embodiments of the present disclosure.

There may be omitted the description of the configuration of the display panel 110 illustrated in FIGS. 7 and 8 that is the same as the configuration of the display panel 110 illustrated in FIG. 4.

The substrate SUB may be disposed at the lowermost part of the display panel 110. A multi-buffer layer MBUF, an active buffer layer ABUF, and a gate insulating film GI may be disposed on the substrate SUB. The active buffer layer ABUF may include a first active buffer layer (not illustrated) and a second active buffer layer (not illustrated).

A first interlayer insulating film ILD1 may be disposed on the gate insulating film GI. The first interlayer insulating film ILD1 may be disposed to cover a gate metal GM disposed on the gate insulating film GI.

A second interlayer insulating film ILD2 may be disposed on the first interlayer insulating film ILD1. The second interlayer insulating film ILD2 may be disposed to cover a jumping metal TM disposed on the first interlayer insulating film ILD1.

The first interlayer insulating film ILD1 and the second interlayer insulating film ILD2 may include a plurality of contact holes.

A first planarization layer PLN1 may be disposed on the second interlayer insulating film ILD2. The first planarization layer PLN1 may be disposed to cover a first source-drain electrode pattern SD1 disposed on the second interlayer insulating film ILD2. A second source-drain electrode pattern SD2 may be disposed on the first planarization layer PLN1. In order for the second source-drain electrode pattern SD2 to be disposed in contact with the first source-drain electrode pattern SD1, a portion of the first planarization layer PLN1 may be etched and removed.

The second planarization layer PLN2 may be disposed on the first planarization layer PLN1. The second planarization layer PLN2 may be disposed to cover the second source-drain electrode pattern SD2 disposed on the second planarization layer PLN2. A portion of the second planarization layer PLN2 may be etched and removed.

A first dam DAM1, a second dam DAM2, and a third dam DAM3 may be disposed on the portion of the second planarization layer PLN2 that is etched and removed. The first dam DAM1 and the second dam DAM2 may include a bank BANK and a spacer SPC disposed on the bank BANK. The third dam DAM3 may include the bank BANK. The first dam DAM1 and the second dam DAM2 may be disposed on the second source-drain electrode pattern SD2. The third dam DAM3 may be disposed on the second planarization layer PLN2. Among the dams DAM1, DAM2 and DAM3, the first dam DAM1 may be disposed closest to a display area (not shown). The second dam DAM2 may be disposed on an outer side of the first dam DAM1, and the third dam DAM3 may be disposed on an outer side of the second dam DAM2. The heights of the first dam DAM1 and the second dam DAM2 may be greater than the height of the third dam DAM3.

The bank BANK may be disposed on the second planarization layer PLN2. The bank BANK may be disposed in a display area (not shown), and the bank BANK may define an emission area (not shown).

A first inorganic encapsulation layer PAS1 may be disposed to cover a portion of the second planarization layer PLN2, the bank BANK, the first dam DAM1, the second dam DAM2, and the third dam DAM3.

An organic encapsulation layer PCL may be disposed on the first inorganic encapsulation layer PAS1. The organic encapsulation layer PCL may be formed by an inkjet method. At this time, the dams DAM1, DAM2 and DAM3 may prevent the organic encapsulation layer PCL from overflowing beyond the outer periphery of the dam.

A second inorganic encapsulation layer PAS2 may be disposed to cover the organic encapsulation layer PCL and the first inorganic encapsulation layer PAS1.

A touch buffer film T-BUF, a bridge metal BRG, a touch interlayer insulating film T-ILD, and a touch sensor metal TSM may be disposed on the second inorganic encapsulation layer PAS2. A color filter buffer film C-BUF, a black matrix BM, and a color filter overcoating layer C-OC may be disposed on the touch sensor metal TSM.

Meanwhile, referring to FIGS. 7 and 8, the first source-drain electrode pattern SD1 may be disposed on the second interlayer insulating film ILD2, but a part of the first source-drain electrode pattern SD1 may be etched and removed. For example, referring to FIG. 7, since a part of the first source-drain electrode pattern SD1 is etched and removed, the first source-drain electrode patterns SD1 may be disposed spaced apart from each other in an outer area OC, a jumping area JA, and a pad area PA.

Referring to FIGS. 7 and 8, a second source-drain electrode pattern SD2 may be disposed on the first planarization layer PLN1, but a part of the second source-drain electrode pattern SD2 may be etched and removed. For example, referring to FIG. 7, as a part of the second source-drain electrode pattern SD2 is etched and removed, the second source-drain electrode patterns SD2 may be arranged to be spaced apart from each other in the outer area OC, the jumping area JA, and the pad area PA.

Referring to FIGS. 7 and 8, the touch sensor metal TSM may be disposed on the touch interlayer insulating film T-ILD, but a part of the touch sensor metal TSM may be etched and removed. For example, referring to FIG. 7, as a part of the touch sensor metal TSM is etched and removed, the touch sensor metals TSM may be disposed in two parts separated from each other in FIG. 7.

Referring to FIG. 7, the touch sensor metal TSM may be included in a first type touch routing line TL1a and a first row touch pad TP1a. Referring to FIG. 8, the touch sensor metal TSM may be included in a second type touch routing line TL1b and a second row touch pad TP1b.

Referring to FIGS. 7 and 8, the bridge metal BRG may be disposed between a first touch buffer film T-BUFa and a second touch buffer film T-BUFb. The touch buffer film T-BUF may include the first touch buffer film T-BUFa disposed on the second inorganic encapsulation layer PAS2, and the second touch buffer film T-BUFb disposed to cover the bridge metal BRG. The touch interlayer insulating film T-ILD and the second touch buffer film T-BUFb may include a contact hole, and the bridge metal BRG may be disposed in contact with the touch sensor metal TSM through the contact hole.

Hereinafter, the touch pads TP1a and TP1b, and the touch routing lines TL1a and TL1b will be described in more detail.

Referring to FIG. 7, the display panel 110 may include the outer area OC, the pad area PA, and the jumping area JA. The pad area PA may be an area where the touch pads TP1 and TP2 are disposed. The jumping area JA may be an area for electrically connecting the jumping metal TM and the touch sensor metal TSM. The jumping area JA may be an area where the jumping metal TM, the first source-drain electrode pattern SD1, the second source-drain electrode pattern SD2, and the touch sensor metal TSM are disposed sequentially. The outer area OC may be an outer area of the display area DA. The jumping area JA may be an area between the outer area OC and the pad area PA.

The pad area PA may be an area where pads for signal transmission are disposed. Referring to FIG. 7, the pad area PA may include a first pad area PAa and a second pad area PAb. The first pad area PAa may be an area where a first row touch pad TP1a is disposed. The second pad area PAb may be an area where a second row touch pad TP1b is disposed.

Referring to FIG. 7, the first row touch pad TP1a may be electrically connected to the first type touch routing line TL1a. Referring to FIG. 8, the second row touch pad TP1b may be electrically connected to the second type touch routing line TL1b. The first touch routing line TL1 may include the first type touch routing line TL1a and the second type touch routing line TL1b.

Referring to FIG. 7, the first row touch pad TP1a may include the first source-drain electrode pattern SD1, the second source-drain electrode pattern SD2, and the touch sensor metal TSM.

In the first pad area PAa, the touch sensor metal TSM may be disposed on the second source-drain electrode pattern SD2. In the first pad area PAa, the second source-drain electrode pattern SD2 may be disposed on the first source-drain electrode pattern SD1.

Referring to FIG. 7, the first row touch pad TP1a may be disposed in contact with the first type touch routing line TL1a in the first pad area PAa.

Referring to FIG. 7, the first type touch routing line TL1a may include the gate metal GM, the jumping metal TM, the second source-drain electrode pattern SD2, the first source-drain electrode pattern SD1, the touch sensor metal TSM, and the bridge metal BRG.

Referring to FIG. 7, the gate metal GM may be disposed in the jumping area JA and the first pad area PAa. The jumping metal TM may be disposed to overlap with the gate metal GM on the gate metal GM. The jumping metal TM may be disposed in the jumping area JA and the first pad area PAa. Referring to FIG. 7, the jumping metal TM and the gate metal GM may be connected in parallel with each other. Accordingly, the resistance value of the metals (e.g., TM, GM) connected in parallel may be reduced.

Referring to FIG. 7, the first source-drain electrode pattern SD1 may be disposed in contact with the gate metal GM and the jumping metal TM. In the jumping area JA, the first source-drain electrode pattern SD1 may be disposed in contact with the jumping metal TM through a contact hole of the second interlayer insulating film ILD2. In the jumping area JA, the second source-drain electrode pattern SD2 may be disposed in contact with the gate metal GM pattern through a contact hole of the first interlayer insulating film ILD1.

Referring to FIG. 7, in the jumping area JA, the second source-drain electrode pattern SD2 may be disposed to overlap with the first source-drain electrode pattern SD1. The second source-drain electrode pattern SD2 may be disposed in contact with the first source-drain electrode pattern SD1 through a contact hole of the first planarization layer PLN1.

Referring to FIG. 7, in the jumping area JA, the touch sensor metal TSM may be disposed to overlap with the second source-drain electrode pattern SD2. Referring to FIG. 7, there is illustrated a contact hole penetrating the second planarization layer PLN2, the first inorganic encapsulation layer PAS1, the second inorganic encapsulation layer PAS2, and the touch interlayer insulating film T-ILD. The touch sensor metal TSM may be disposed in contact with the second source-drain electrode pattern SD2 through the contact hole penetrating the second planarization layer PLN2, the first inorganic encapsulation layer PAS1, the second inorganic encapsulation layer PAS2, and the touch interlayer insulating film T-ILD.

Referring to FIG. 7, the touch sensor metal TSM may be disposed in the outer area OC. The touch sensor metal TSM may be disposed in contact with the bridge metal BRG through a contact hole of the touch interlayer insulating film T-ILD.

Referring to FIG. 8, the second row touch pad TP1b may include the first source-drain electrode pattern SD1, the second source-drain electrode pattern SD2, and the touch sensor metal TSM.

In the second pad area PAb, the touch sensor metal TSM may be disposed on the second source-drain electrode pattern SD2. In the second pad area PAb, the second source-drain electrode pattern SD2 may be disposed on the first source-drain electrode pattern SD1.

Referring to FIG. 8, the second row touch pad TP1b may be disposed in contact with the second type touch routing line TL1b in the second pad area PAb.

Referring to FIG. 8, the second type touch routing line TL1b may include the gate metal GM, the jumping metal TM, the second source-drain electrode pattern SD2, the first source-drain electrode pattern SD1, the touch sensor metal TSM, and the bridge metal BRG.

Referring to FIG. 8, the gate metal GM may be disposed in the jumping area JA, the first pad area PAa, and the second pad area PAb. The jumping metal TM may be disposed on the gate metal GM to overlap with the gate metal GM. The jumping metal TM may be disposed in the jumping area JA, the first pad area PAa, and the second pad area PAb.

Referring to FIG. 8, the first source-drain electrode pattern SD1 may be disposed in contact with the gate metal GM and the jumping metal TM. In the jumping area JA, the first source-drain electrode pattern SD1 may be disposed in contact with the jumping metal TM through a contact hole of the second interlayer insulating film ILD2. In the jumping area JA, the second source-drain electrode pattern SD2 may be disposed in contact with the gate metal GM pattern through a contact hole of the first interlayer insulating film ILD1.

Referring to FIG. 8, in the jumping area JA, the second source-drain electrode pattern SD2 may be disposed to overlap with the first source-drain electrode pattern SD1. The second source-drain electrode pattern SD2 may be disposed in contact with the first source-drain electrode pattern SD1 through a contact hole of the first planarization layer PLN1.

Referring to FIG. 8, in the jumping area JA, the touch sensor metal TSM may be disposed to overlap with the second source-drain electrode pattern SD2. Referring to FIG. 8, there is illustrated a contact hole penetrating the second planarization layer PLN2, the first inorganic encapsulation layer PAS1, the second inorganic encapsulation layer PAS2, and the touch interlayer insulating film T-ILD. The touch sensor metal TSM may be disposed to contact the second source-drain electrode pattern SD2 through the contact hole penetrating the second planarization layer PLN2, the first inorganic encapsulation layer PAS1, the second inorganic encapsulation layer PAS2, and the touch interlayer insulating film T-ILD.

Referring to FIG. 8, the touch sensor metal TSM may be disposed in the outer area OC. The touch sensor metal TSM may be disposed in contact with the bridge metal BRG through a contact hole of the touch interlayer insulating film T-ILD.

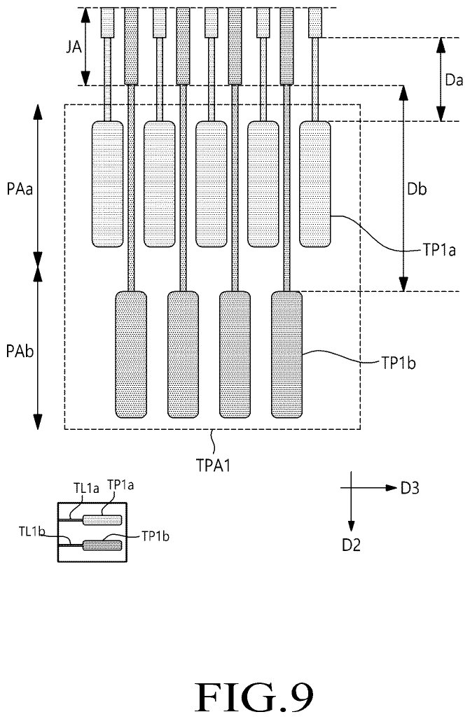

Referring to FIG. 7 and FIG. 8, a second length Db from the jumping area JA of the second type touch routing line TL1b to the second row touch pad TP1b may be greater than a first length Da from the jumping area JA of the first type touch routing line TL1a to the first row touch pad TP1a. Hereinafter, the first length Da and the second length Db will be described in more detail with reference to FIG. 9.

FIG. 9 is a plan view of a touch routing line TL and a touch pad TP according to embodiments of the present disclosure.

Referring to FIG. 9, there is illustrated the first pad area PAa shown in FIG. 5 and FIG. 6.

Referring to FIG. 9, five first row touch pads TP1a may be disposed in the first pad area PAa. Four second row touch pads TP1b may be disposed in the second pad area PAb.

The first row touch pads TP1a may be electrically connected to the first type touch routing line TL1a. Referring to FIG. 9, five first type touch routing lines TL1a may be electrically connected to five first row touch pads TP1a.

The second row touch pads TP1b may be electrically connected to the second type touch routing lines TL1b. Referring to FIG. 9, four second type touch routing lines TL1b are electrically connected to four second row touch pads TP1b.

Referring to FIG. 9, a second length Db from the jumping area JA of the second type touch routing line TL1b to the second row touch pad TP1b may be greater than a first length Da from the jumping area JA of the first type touch routing line TL1a to the first row touch pad TP1a.

Since the second type touch routing line TL1b is longer than the first type touch routing line TL1a, the resistance value of the second type touch routing line TL1b may become larger. The resistance value of a wire or a line may become larger as the length of the wire or the line becomes longer.

That is, the resistance value of the first type touch routing line TL1a and the resistance value of the second type touch routing line TL1b may be different from each other. Accordingly, there may be a difference in the transmission speed of the signal transmitted through each of the first type touch routing line TL1a and the second type touch routing line TL1b.

Here, if a design of the first type touch routing line TL1a is changed, there may reduce the difference in resistance value between the first type touch routing line TL1a and the second type touch routing line TL1b. An example of this will be described below.

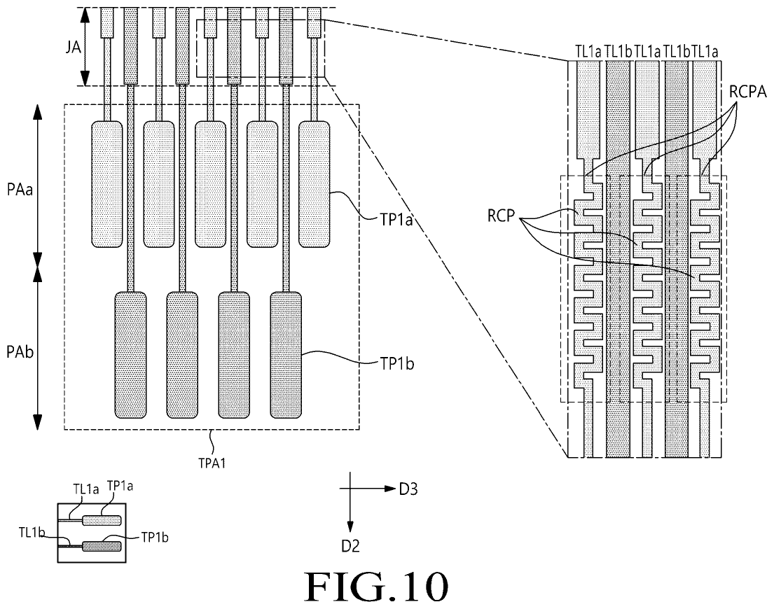

FIG. 10 is a plan view of a touch routing line TL and a touch pad TP according to embodiments of the present disclosure.

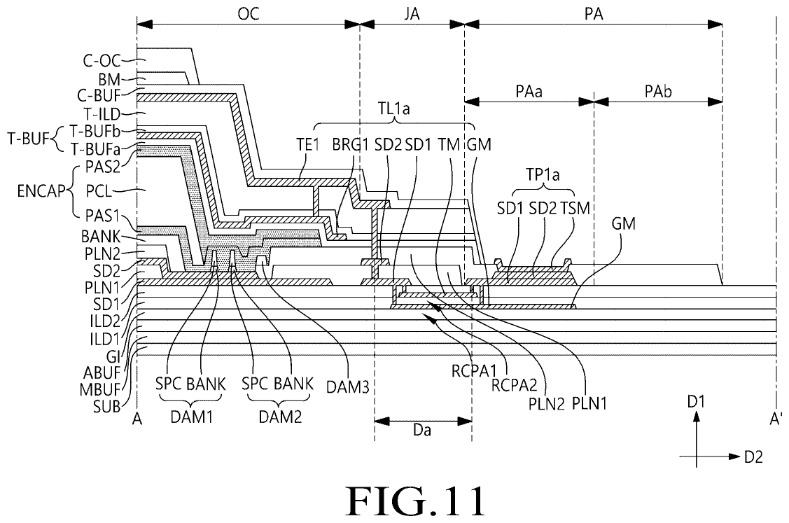

FIG. 11 is a plan view of a touch routing line TL and a touch pad TP according to embodiments of the present disclosure.

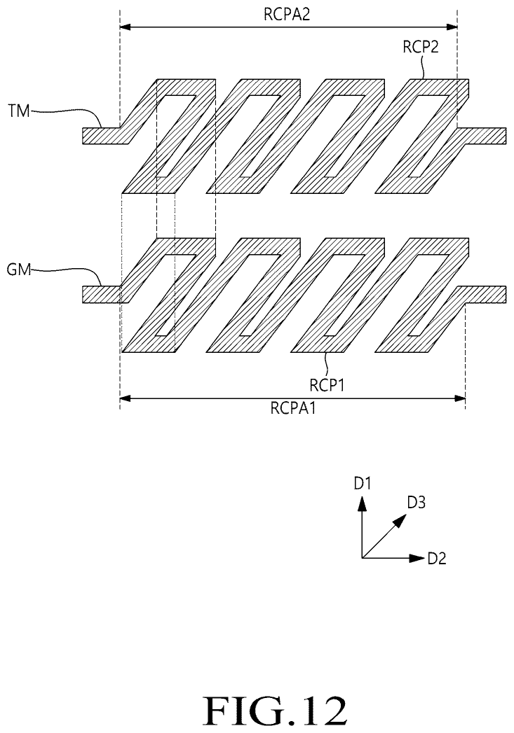

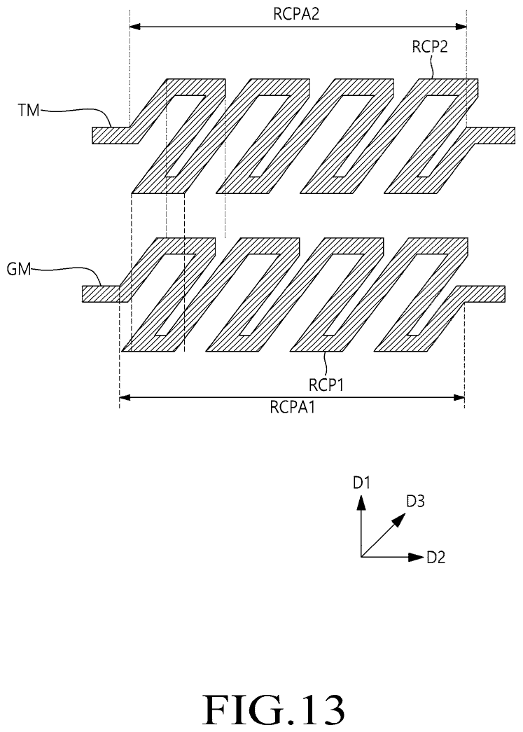

FIGS. 12 and 13 illustrate the resistance compensation patterns RCP according to embodiments of the present disclosure.

Referring to FIG. 10, the first type touch routing line TL1a may include a resistance compensation pattern RCP. In contrast, the second type touch routing line TL1b does not include the resistance compensation pattern RCP. Since the first type touch routing line TL1a includes the resistance compensation pattern RCP, the difference in resistance values between the first type touch routing line TL1a and the second type touch routing line TL1b may be reduced. The resistance compensation pattern RCP of the first type touch routing line TL1a can be provided in various forms. For example, the resistance compensation pattern RCP can be provided in a meandering shape when seen from a plan view (e.g., the line follows a path with curves or bends instead of being straight). The meandering shape of the first type touch routing line TL1a is configured to increase the resistance value of the first type touch routing line TL1a such that the difference in resistance values between the first type touch routing line TL1a and the second type touch routing line TL1b are reduced. To further elaborate, resistance value (R=ρL/A) increases when the length L of the material (e.g., routing line) is increased. Because the second pad area PAb is located farther from the first pad area PAa, the meandering shape of the first type touch routing line TL1a reduces the difference in resistance values between the first type touch routing line TL1a and the second type touch routing line TL1b.

Referring to FIG. 10, five first type touch routing lines TL1a and four second type touch routing lines TL1b are illustrated in the jumping area JA. The first type touch routing line TL1a may include a resistance compensation pattern RCP.

The first type touch routing line TL1a may be electrically connected to the first row touch pad TP1a, and may include a resistance compensation pattern RCP.

The second type touch routing line TL1b may be electrically connected to the second touch pad. The second type touch routing line TL1b may be electrically connected to the second row touch pad TP1b by passing through the first pad area PAa.

Referring to FIG. 10, there may be defined a resistance compensation pattern area RCPA in which a resistance compensation pattern RCP is disposed. In FIG. 10, there is illustrated a case in which three first type touch routing lines TL1a and two second type touch routing lines TL1b are disposed in the resistance compensation pattern area RCPA.

In the resistance compensation pattern area RCPA, the second type touch routing line TL1b may be disposed to extend from top to bottom. The first type touch routing line TL1a may be arranged to extend from top to bottom, and may include a resistance compensation pattern RCP in the middle. The resistance compensation pattern RCP which has a meandering shape may be in a zigzag shape, an oscillating shape, a winding shape, a curving shape, a square wave shape, or various other irregular shapes suitable for compensating the resistance value from a plan view. Since the resistance compensation pattern RCP is disposed in a zigzag shape, the total length of the first type touch routing line TL1a may be increased. Accordingly, the resistance value of the first type touch routing line TL1a may be increased, so that it is possible to reduce the difference in resistance values between the first type touch routing line TL1a and the second type touch routing line TL1b.

Referring to FIG. 10, the resistance compensation pattern RCP is illustrated in the resistance compensation pattern area RCPA, and the first type touch routing line TL1a other than the three first type touch routing lines TL1a of the resistance compensation pattern area RCPA may also include the resistance compensation pattern RCP.

Referring to FIG. 11, it is illustrated a resistance compensation pattern area RCPA in which a resistance compensation pattern RCP that may, for example, include resistance compensation patterns RCP1 and RCP2 (see FIGS. 11 and 12, for example) is formed.

Referring to FIG. 11, the resistance compensation pattern area RCPA may include a first resistance compensation pattern area RCPA1 and a second resistance compensation pattern area RCPA2. The first resistance compensation pattern area RCPA1 may be an area in which a resistance compensation pattern RCP1 (see FIGS. 11 and 12, for example) included in a gate metal GM is disposed. The second resistance compensation pattern area RCPA2 may be an area in which a resistance compensation pattern RCP2 (see FIGS. 11 and 12, for example) included in a jumping metal TM is disposed.

Referring to FIG. 11, the jumping metal TM may be disposed to overlap with the gate metal GM. Referring to FIG. 12, there are illustrated the gate metal GM and the jumping metal TM disposed to overlap with the gate metal GM.

Referring to FIGS. 12 and 13, there are illustrated a first direction D1, a second direction D2, and a third direction D3. The first direction D1 may be a height direction, the second direction D2 may be a horizontal direction, and the third direction D3 may be a vertical direction.

Referring to FIGS. 12 and 13, the first resistance compensation pattern area RCPA1 may overlap with the second resistance compensation pattern area RCPA2 in the height direction D1. The resistance compensation pattern RCP1 included in the gate metal GM may be disposed in the first resistance compensation pattern area RCPA1, and the resistance compensation pattern RCP2 included in the jumping metal TM may be disposed in the second resistance compensation pattern area RCPA2.

Referring to FIG. 12 and FIG. 13, the resistance compensation pattern RCP2 included in the jumping metal TM may overlap with the resistance compensation pattern RCP1 included in the gate metal GM in the height direction D1.

Referring to FIG. 12, the resistance compensation pattern RCP1 of the gate metal GM may have the same shape as the resistance compensation pattern RCP2 of the jumping metal TM. In this case, the zigzag-shaped position of the resistance compensation pattern RCP1 of the gate metal GM may be identical to the zigzag-shaped position of the resistance compensation pattern RCP2 of the jumping metal TM.

Referring to FIG. 13, the resistance compensation pattern RCP1 of the gate metal GM may have the same shape as the resistance compensation pattern RCP2 of the jumping metal TM. However, the zigzag-shaped position of the resistance compensation pattern RCP1 of the gate metal GM may be different from the zigzag-shaped position of the resistance compensation pattern RCP2 of the jumping metal TM.

Referring to FIG. 12 and FIG. 13, the resistance compensation pattern RCP may be arranged so that the zigzag shape extends in the horizontal direction D2. The resistance compensation pattern RCP may include a plurality of uneven patterns. Since the first type touch routing line TL1a includes the resistance compensation pattern RCP, the length of the first type touch routing line TL1a may be relatively increased. Accordingly, there may be reduced the difference in resistance values between the first type touch routing line TL1a and the second type touch routing line TL1b.

Referring to FIGS. 12 and 13, the resistance compensation pattern RCP is exemplified as a regularly repeating uneven shape or a zigzag shape, but the resistance compensation pattern RCP may also be an irregularly repeating uneven shape.

Hereinafter, it will be described a structure of the first row touch pad TP1a.

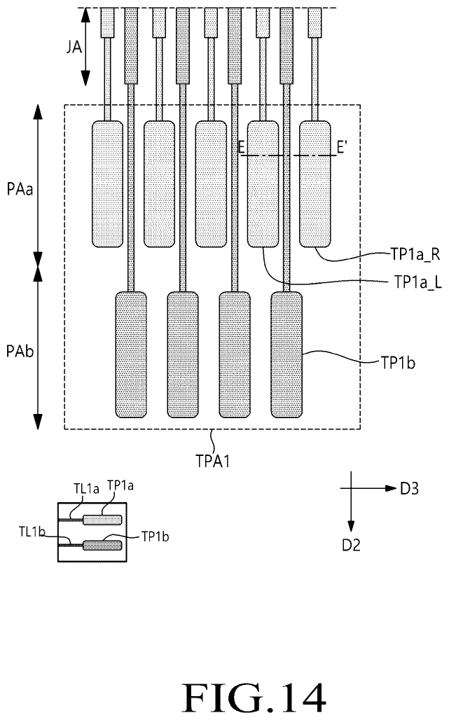

FIG. 14 is a plan view of a touch routing line TL and a touch pad TP according to embodiments of the present disclosure.

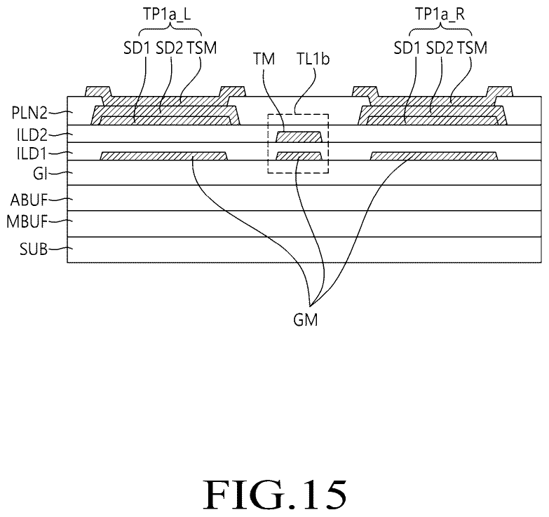

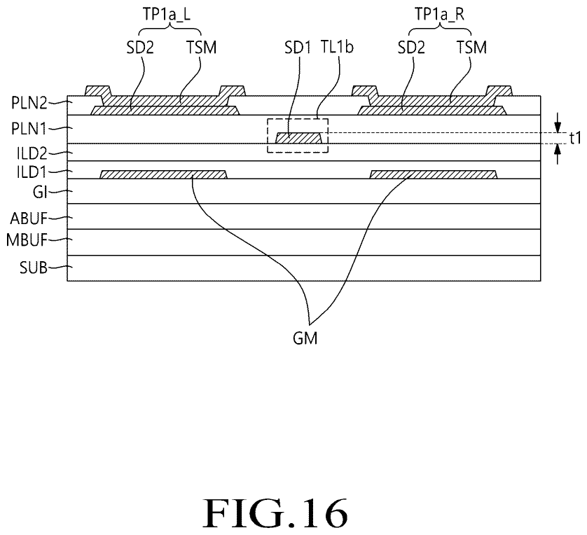

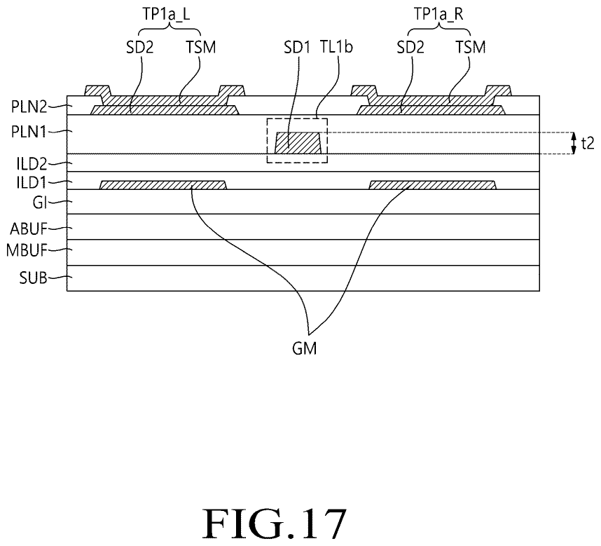

FIG. 15, FIG. 16, and FIG. 17 are cross-sectional views of touch pads TP1a_L and TPa_R and a second type touch routing line TL1b disposed in a first pad area PAa according to embodiments of the present disclosure.

Referring to FIG. 14, five first row touch pads TP1a may be disposed in the first pad area PAa. Four second row touch pads TP1b may be disposed in the second pad area PAb.

The first row touch pad TP1a may be electrically connected to the first type touch routing line TL1a. The second row touch pad TP1b may be electrically connected to the second type touch routing line TL1b.

Referring to FIG. 14, the second type touch routing line TL1b disposed on the far right in the plan view may be arranged in an area between the first row touch pad TP1a_L on the left and the first row touch pad TP1a_R on the right.

Referring to FIG. 14, there is illustrated the E-E′ area. FIGS. 15, 16, and 17 illustrate a cross-sectional view of the E-E′ area.

Referring to FIG. 15, the gate metal GM may be disposed on the gate insulating film GI. A substrate SUB, a multi-buffer layer MBUF, and an active buffer layer ABUF may be disposed under the gate insulating film GI. Referring to FIG. 15, the gate metal GM may be patterned and arranged in three parts separated from each other. Two parts of the gate metal GM may be disposed at a lower portion of the left first row touch pad TP1a_L and a lower portion of the right first row touch pad TP1a_R. The remaining part of the gate metal GM may be disposed between the left first row touch pad TP1a_L and the right first row touch pad TP1a_R.

Referring to FIG. 15, the left first row touch pad TP1a_L may include a first source-drain electrode pattern SD1, a second source-drain electrode pattern SD2, and a touch sensor metal TSM. The left first row touch pad TP1a_L may be disposed to overlap with the gate metal GM disposed at the bottom of the left first row touch pad TP1a_L.

Referring to FIG. 15, the right first row touch pad TP1a_R on the right may include a first source-drain electrode pattern SD1, a second source-drain electrode pattern SD2, and a touch sensor metal TSM. The right first row touch pad TP1a_R may be disposed to overlap with a gate metal GM disposed at the bottom of the right first row touch pad TP1a_R.

Referring to FIG. 15, the second type touch routing line TL1b may be disposed between the left first row touch pad TP1a_L and the right first row touch pad TP1a_R. The second type touch routing line TL1b may include a gate metal GM and a jumping metal TM. The jumping metal TM may be disposed to overlap with the gate metal GM.

Referring to FIG. 15, the second type touch routing line TL1b may be disposed so as not to overlap with the left first row touch pad TP1a_L and the right first row touch pad TP1a_R.

Referring to FIG. 15, a first interlayer insulating film ILD1 may be disposed to cover the gate metal GM. A second interlayer insulating film ILD2 may be disposed on the first interlayer insulating film ILD1, and the second interlayer insulating film ILD2 may be disposed to cover the jumping metal TM. A second planarization layer PLN2 may be disposed on the second interlayer insulating film ILD2. After the second planarization layer PLN2 is disposed to cover the second source-drain electrode pattern SD2, a portion of the second planarization layer PLN2 may be etched and removed. A touch sensor metal TSM may be disposed on the etched second planarization layer PLN2, and the touch sensor metal TSM may be disposed in contact with the second source-drain electrode pattern SD2.

Referring to FIG. 16 and FIG. 17, the configurations of the first row touch pads TP1a and the second type touch routing line TL1b may be designed differently.

Referring to FIG. 16, the gate metal GM may be disposed on the gate insulating film GI, but may be disposed in an area overlapping with the first row touch pad TP1a.

Referring to FIG. 16, the first interlayer insulating film ILD1 may be disposed to cover two gate metals GM.

Referring to FIG. 16, the second interlayer insulating film ILD2 may be disposed on the first interlayer insulating film ILD1.

Referring to FIG. 16, the first source-drain electrode pattern SD1 may be disposed in an area that does not overlap with the gate metal GM. The first source-drain electrode pattern SD1 may be a second type touch routing line TL1b.

Referring to FIG. 16, a first planarization layer PLN1 may be disposed to cover the first source-drain electrode pattern SD1. The second source-drain electrode pattern SD2 may be disposed on the first planarization layer PLN1.

Referring to FIG. 16, the second planarization layer PLN2 may be disposed to cover the second source-drain electrode pattern SD2. After the second planarization layer PLN2 is disposed to cover the second source-drain electrode pattern SD2, a portion of the second planarization layer PLN2 may be etched and removed. A touch sensor metal TSM may be disposed on the etched second planarization layer PLN2, and the touch sensor metal TSM may be disposed to be in contact with the second source-drain electrode pattern SD2.

Referring to FIG. 16, the first row touch pad TP1a_L on the left may include a second source-drain electrode pattern SD2 and a touch sensor metal TSM. The first row touch pad TP1a_L on the left may be disposed to overlap with a gate metal GM disposed under the first row touch pad TP1a_L on the left.

Referring to FIG. 16, the first row touch pad TP1a_R on the right may include a second source-drain electrode pattern SD2 and a touch sensor metal TSM. The first row touch pad TP1a_R on the right may be disposed to overlap with a gate metal GM disposed under the first row touch pad TP1a_R on the right.

Referring to FIG. 15, the second type touch routing line TL1b may include a jumping metal TM and a gate metal GM. Alternatively, referring to FIG. 16, the second type touch routing line TL1b may include a first source-drain electrode pattern SD1.

The resistance value of the first source-drain electrode pattern SD1 may be smaller than the resistance value of the jumping metal TM and the resistance value of the gate metal GM. That is, the material included in the first source-drain electrode pattern SD1 may be a material having a lower resistance than the resistance of the material of the jumping metal TM and the material of the gate metal GM. For example, the first source-drain electrode pattern SD1 may include aluminum (Al), and the jumping metal TM and the gate metal GM may include molybdenum (Mo). However, this is only an example, and the material included in the first source-drain electrode pattern SD1 may be any material having a resistance value lower than the resistance values of the material of the jumping metal TM and the material of the gate metal GM.

Unlike that illustrated in FIG. 15, the second type touch routing line TL1b illustrated in FIG. 16 may include the first source-drain electrode pattern SD1, so that the resistance value of the second type touch routing line TL1b may be relatively lowered. Accordingly, there may be reduced the difference in resistance values between the first type touch routing line TL1a and the second type touch routing line TL1b.

Meanwhile, referring to FIG. 17, a thickness t2 of the second type touch routing line TLb may be relatively increased. The thickness t2 of the second type touch routing line TL1b illustrated in FIG. 17 may be greater than a thickness t1 of the second type touch routing line TL1b illustrated in FIG. 16.

As the thickness of the second type touch routing line TL1b is increased, the resistance value of the second type touch routing line TL1b may be further reduced.

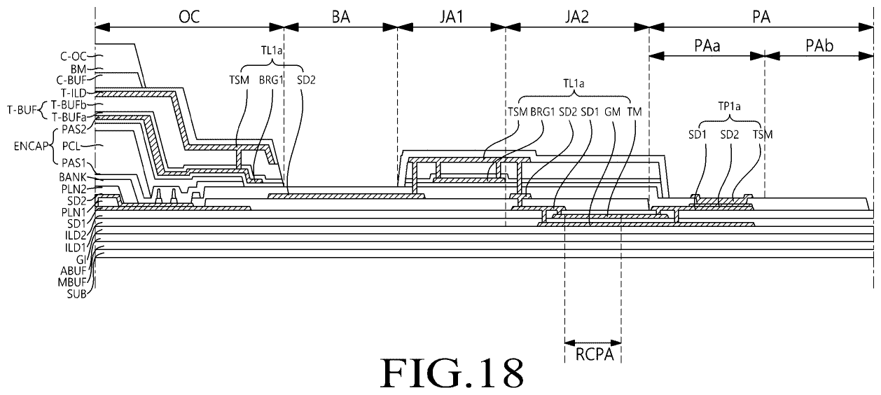

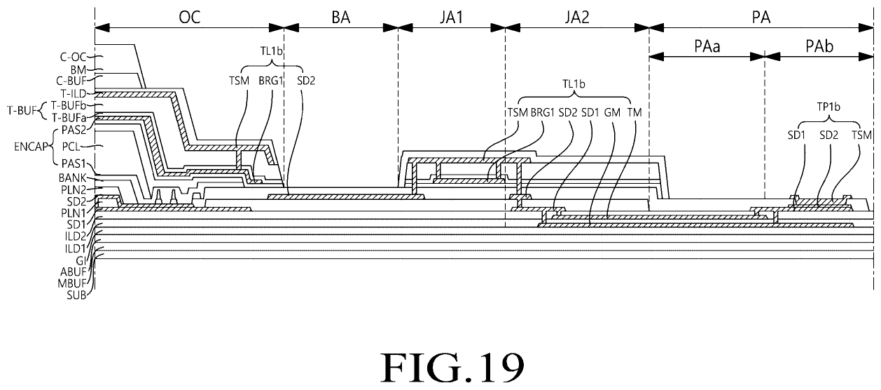

FIG. 18 and FIG. 19 are cross-sectional views of touch routing line TL and a touch pad TP according to embodiments of the present disclosure.

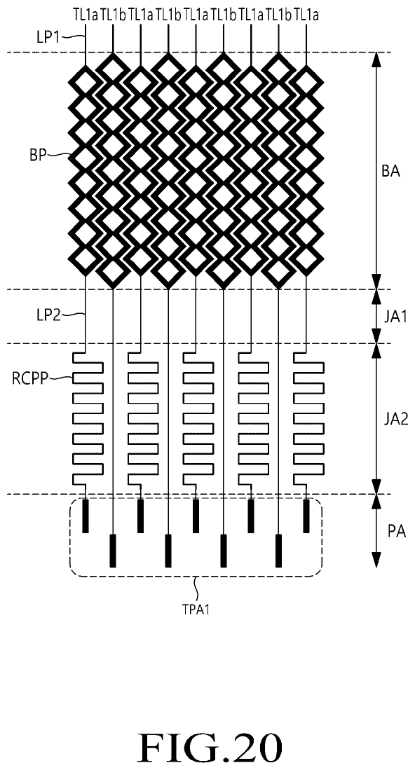

FIG. 20 is a plan view of touch routing line TL and a touch pad TP according to embodiments of the present disclosure.

There may be omitted the description of the configuration of the display panel 110 of FIGS. 18 and 19 corresponding to the configuration of the display panel 110 illustrated in FIGS. 7 and 8.

Referring to FIGS. 18 and 19, the display panel 110 may further include a bending area BA between the outer area OC and the jumping area JA. The bending area BA illustrated in FIGS. 18 and 19 may correspond to the bending area BA illustrated in FIG. 6.

Referring to FIG. 18, in the outer area OC, the touch sensor metal TSM may be disposed in contact with the bridge metal BRG through a contact hole. The contact hole may be formed by penetrating the touch interlayer insulating film T-ILD and the second touch buffer film T-BUFb.

Referring to FIG. 18, in the outer area OC, the touch sensor metal TSM may be disposed in contact with the second source-drain electrode pattern SD2 through a contact hole. The contact hole may be formed by penetrating the touch interlayer insulating film T-ILD, the second touch buffer film T-BUFb, the first touch buffer film T-BUFa, and the second planarization layer PLN2.

Referring to FIG. 18, the second source-drain electrode pattern SD2 disposed in contact with the touch sensor metal TSM in the outer area OC may also be disposed in the bending area BA and a first jumping area JA1.

Referring to FIG. 18, in the bending area BA, the second planarization layer PLN2 may be disposed to cover the second source-drain electrode pattern SD2. Unlike other areas, the bending area BA may not have other layers disposed on the second planarization layer PLN2. Accordingly, the bending area BA may be bent. Referring to FIG. 18, it is illustrated a case in which the second source-drain electrode pattern SD2 is disposed in the bending area BA, however, any one of the first source-drain electrode pattern SD1, the jumping metal TM, and the gate metal GM may be disposed in the bending area BA instead of the second source-drain electrode pattern SD2.

Referring to FIG. 18, it is illustrated the first jumping area JA1 and the second jumping area JA2. The touch buffer film T-BUF, the touch interlayer insulating film T-ILD, and the color filter buffer film C-BUF may not be disposed in the bending area BA. On the other hand, the touch buffer film T-BUF, the touch interlayer insulating film T-ILD, and the color filter buffer film C-BUF may be disposed in the first jumping area JA1 and the second jumping area JA2.

Referring to FIG. 18, in the first jumping area JA1, the first source-drain electrode pattern SD1 may be disposed in contact with the touch sensor metal TSM. The touch sensor metal TSM may be disposed in contact with the bridge metal BRG. The bridge metal BRG may be disposed between the first touch buffer film T-BUFa and the second touch buffer film T-BUFb. The bridge metal BRG may be disposed to overlap with the touch sensor metal TSM.

Referring to FIG. 18, in the first jumping area JA1, the bridge metal BRG may be disposed to contact the touch sensor metal TSM at the left end of the bridge metal BRG. The bridge metal BRG may be disposed to contact the touch sensor metal TSM at the right end of the bridge metal BRG.

Referring to FIG. 18, in the first jumping area JA1 and the second jumping area JA2, the touch interlayer insulating film T-ILD may be disposed on the second touch buffer film T-BUFb. The touch sensor metal TSM may be disposed on the touch interlayer insulating film T-ILD. A color filter buffer film C-BUF may be disposed to cover the touch interlayer insulating film T-ILD.

Referring to FIG. 18, the characteristics of the second jumping area JA2 illustrated in FIG. 18 may be the same as the characteristics of the jumping area JA illustrated in FIG. 7.

Referring to FIG. 18, in the second jumping area JA2, the touch sensor metal TSM may be disposed in contact with the second source-drain electrode pattern SD2. The second source-drain electrode pattern SD2 may be disposed in contact with the first source-drain electrode pattern SD1. The first source-drain electrode pattern SD1 may be disposed in contact with the gate metal GM and the jumping metal TM.

Referring to FIG. 18, in the second jumping area JA2, the second source-drain electrode pattern SD2 may be disposed in contact with the touch sensor metal TSM, and the second source-drain electrode pattern SD2 may be disposed in contact with the first source-drain electrode pattern SD1. The jumping metal TM may be disposed in contact with the gate metal GM.

Referring to FIG. 18, a first row touch pad TP1a may be disposed in the first pad area PAa. The first row touch pad TP1a may include a touch sensor metal TSM, a second source-drain electrode pattern SD2, and a first source-drain electrode pattern SD1. The first source-drain electrode pattern SD1 described above may be disposed in contact with the jumping metal TM and the gate metal GM.

Referring to FIG. 18, there is illustrated a resistance compensation pattern area RCPA. The jumping metal TM corresponding to the resistance compensation pattern area RCPA may include a resistance compensation pattern RCP. The gate metal GM corresponding to the resistance compensation pattern area RCPA may include a resistance compensation pattern RCP.

Referring to FIG. 19, a second type touch routing line TL1b and a second row touch pad TP1b are illustrated. The second type touch routing line TL1b illustrated in FIG. 19, unlike the first type touch routing line TL1a illustrated in FIG. 18, may pass through the lower portion of the first row touch pad TP1a, and may be electrically connected to the second row touch pad TP1b.

Referring to FIG. 20, it is illustrated a plan view of the first type touch routing line TL1a and the second type touch routing line TL1b.

The first type touch routing line TL1a and the second type touch routing line TL1b may be electrically connected to pads disposed in the pad area PA.

Referring to FIG. 20, the first type touch routing line TL1a may include a first line portion LP1, a bending pattern portion BP, a second line portion LP2, and a resistance compensation pattern portion RCP.

Referring to FIG. 20, the second type touch routing line TL1b may include a first line portion LP1, a bending pattern portion BP, and a second line portion LP2.

The bending pattern portion BP may correspond to the bending area BA. The bending pattern portion BP may be in the form of unfilled polygons (preferably, diamonds) whose edges are connected in a row. Alternatively, the bending pattern portion BP may be in the form of unfilled circles connected in a row. Due to the form of the bending pattern portion BP described above, cracks may not occur in the touch routing lines TL1a and TL1b even if the bending area BA is bent.

The second line portion LP2 may correspond to the first jumping area JA1. The second line portion LP2 may be in a straight line shape. The second line portion LP2 may be arranged to extend from top to bottom.

The resistance compensation pattern portion RCP may correspond to the second jumping area JA2. The resistance compensation pattern RCP may be in a zigzag shape. Referring to FIG. 20, each of the five first type touch routing lines TL1a may include a resistance compensation pattern RCP of the same shape. Alternatively, each of the five first type touch routing lines TL1a may include a resistance compensation pattern RCP of a different shape.

The first type touch routing line TL1a may include a resistance compensation pattern portion RCP, but the second type touch routing line TL1b may not include a resistance compensation pattern portion RCP. Since the first type touch routing line TL1a includes a resistance compensation pattern portion RCP, there may be reduced the difference between the resistance value of the first type touch routing line TL1a and the resistance value of the second type touch routing line TL1b. In this case, the resistance value of the first type touch routing line TL1a and the resistance value of the second type touch routing line TL1b may be the same.

The difference between the resistance value of the first type touch routing line TL1a and the resistance value of the second type touch routing line TL1b may be reduced, so that it is possible to reduce the deviation in the signal transmission speed between the touch routing lines.

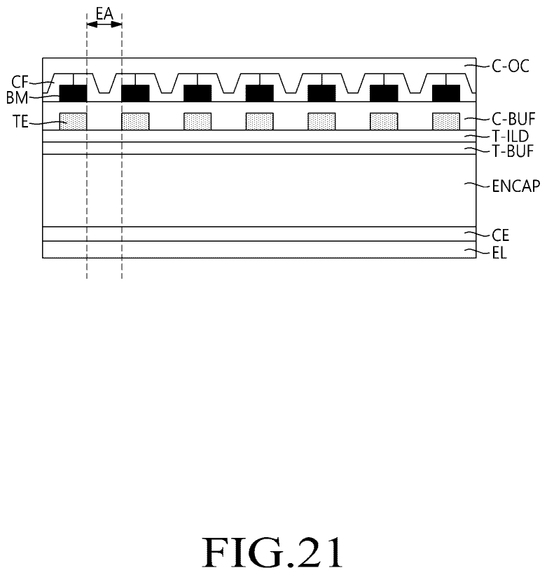

FIG. 21 is a plan view of a display panel 110 in which a color filter CF is disposed on an encapsulation layer ENCAP according to embodiments of the present disclosure.

Referring to FIG. 21, there is schematically illustrated a cross-sectional view of a display device 100 in which a color filter CF is disposed on an encapsulation layer ENCAP. This may be referred to as a CoE structure.

Referring to FIG. 21, a cathode electrode CE may be disposed on an emission layer EL. An encapsulation layer ENCAP, a touch buffer film T-BUF, and a touch interlayer insulating film T-ILD may be disposed sequentially on the cathode electrode CE.

Referring to FIG. 21, a touch electrode TE may be disposed on the touch interlayer insulating film T-ILD.

Referring to FIG. 21, a color filter buffer film C-BUF may be disposed to cover the touch electrodes TE.

Referring to FIG. 21, a black matrix BM may be disposed at a position corresponding to the touch electrodes TE.

Referring to FIG. 21, a color filter CF may be disposed in contact with a part of the color filter buffer film C-BUF and the black matrix BM.

Referring to FIG. 21, a color filter overcoating layer C-OC may be disposed to cover the color filter CF.

Referring to FIG. 21, the touch electrodes TE may be disposed to overlap the black matrix BM. The emission area EA may be an area between the touch electrodes TE or an area between the black matrix BM. The color filter CF and an emission layer EL may be disposed in the emission area EA.

Embodiments of the present disclosure described above are briefly described as follows.

A display device according to embodiments of the present disclosure may include a substrate including a display area, a first pad area, and a second pad area, a first touch pad disposed in the first pad area, a second touch pad disposed in the second pad area, which is an area of an edge of the substrate, a first touch routing line electrically connected to the first touch pad, and including a resistance compensation pattern, and a second touch routing line electrically connected to the second touch pad.

The second touch routing line may pass through the first pad area between the display area and the second pad area, and may be electrically connected to the second touch pad.

The resistance compensation pattern of the first touch routing line may have a zigzag shape.

The display device according to embodiments of the present disclosure may further include a gate metal disposed on the substrate, and disposed in the first pad area and a jumping area between the first pad area and the display area, a metal pattern overlapping with at least a portion of the gate metal, a first source-drain electrode pattern disposed on the gate metal and the metal pattern, and electrically connected to the gate metal and the metal pattern in the jumping area, a second source-drain electrode pattern disposed on the first source-drain electrode pattern, and electrically connected to the first source-drain electrode pattern, and a touch sensor metal disposed on the second source-drain electrode pattern, and electrically connected to the second source-drain electrode pattern. In this case, the first touch routing line may include at least one of the gate metal, the metal pattern, the first source-drain electrode pattern, the second source-drain electrode pattern, or the touch sensor metal.

The gate metal of the first touch routing line and the metal pattern of the first touch routing line may include the resistance compensation pattern.

The resistance compensation pattern formed on the gate metal may overlap with at least a portion of the resistance compensation pattern formed on the metal pattern.

The resistance compensation pattern formed on the gate metal may have a different shape from the resistance compensation pattern formed on the metal pattern.

The second touch routing line may include a gate metal disposed in the first pad area, and disposed in an area not overlapping with the first touch pad, and a metal pattern disposed overlapping with the gate metal.

The display device according to embodiments of the present disclosure may further include a first source-drain electrode pattern disposed on the substrate, and included in the second routing line, a first planarization layer disposed to cover the first source-drain electrode pattern, a second source-drain electrode pattern disposed on the first planarization layer, and included in the first touch pad, and a touch sensor metal disposed in contact with the second source-drain electrode pattern, and included in the first touch pad.

A material of the first source-drain electrode pattern included in the second touch routing line may be different from a material of the second source-drain electrode pattern included in the first touch pad.

A thickness of the first source-drain electrode pattern included in the second touch routing line may be greater than a thickness of the second source-drain electrode pattern included in the first touch pad.

A length of the first touch routing line may be smaller than a length of the second touch routing line.

The first touch routing line may further include a bending pattern corresponding to a bending area, which is an area between the display area and the first pad area. Optionally, the bending pattern may be in the form of unfilled polygons whose edges are connected in a row or in the form of unfilled circles connected in a row.

The display device according to embodiments of the present disclosure may further include a planarization layer disposed to cover the second source-drain electrode pattern, an emission layer disposed on the planarization layer, an encapsulation layer disposed to cover the emission layer, a first touch electrode electrically connected to the first touch routing line, and disposed on the encapsulation layer, and a second touch electrode electrically connected to the first touch routing line, and disposed on the encapsulation layer.

The display device according to embodiments of the present disclosure may further include a black matrix disposed to overlap with the first touch electrode, and a color filter disposed to overlap with the emission layer.

The first touch routing line and the second touch routing line may be disposed alternately in a jumping area between the first pad area and the display area, the second touch routing line may extend in a straight line in a first direction in the jumping area, and the resistance compensation pattern is disposed in a zigzag shape with respect to the first direction in the jumping area.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area, a first pad area, and a second pad area;
a first touch pad disposed in the first pad area;
a second touch pad disposed in the second pad area, which is an area of an edge of the substrate;
a first touch routing line electrically connected to the first touch pad, the first touch routing line including a resistance compensation pattern; and
a second touch routing line electrically connected to the second touch pad.

2. The display device of claim 1, wherein the second touch routing line passes through the first pad area between the display area and the second pad area, and is electrically connected to the second touch pad.

3. The display device of claim 1, wherein the resistance compensation pattern of the first touch routing line has a zigzag shape.

4. The display device of claim 1, further comprising:
a gate metal disposed on the substrate, and disposed in the first pad area and a jumping area between the first pad area and the display area;
a metal pattern overlapping with at least a portion of the gate metal;
a first source-drain electrode pattern disposed on the gate metal and the metal pattern, and electrically connected to the gate metal and the metal pattern in the jumping area;
a second source-drain electrode pattern disposed on the first source-drain electrode pattern, and electrically connected to the first source-drain electrode pattern; and
a touch sensor metal disposed on the second source-drain electrode pattern, and electrically connected to the second source-drain electrode pattern,
wherein the first touch routing line includes at least one of the gate metal, the metal pattern, the first source-drain electrode pattern, the second source-drain electrode pattern, or the touch sensor metal.

5. The display device of claim 4, wherein the gate metal of the first touch routing line and the metal pattern of the first touch routing line include the resistance compensation pattern.

6. The display device of claim 5, wherein the resistance compensation pattern disposed on the gate metal overlaps with at least a portion of the resistance compensation pattern disposed on the metal pattern.

7. The display device of claim 5, wherein the resistance compensation pattern disposed on the gate metal has a different shape from the resistance compensation pattern disposed on the metal pattern.

8. The display device of claim 1, wherein the second touch routing line includes:
a gate metal disposed in the first pad area, and disposed in an area not overlapping with the first touch pad; and
a metal pattern disposed overlapping with the gate metal.

9. The display device of claim 1, further comprising:
a first source-drain electrode pattern disposed on the substrate, and included in the second routing line;
a first planarization layer disposed to cover the first source-drain electrode pattern;
a second source-drain electrode pattern disposed on the first planarization layer, and included in the first touch pad; and
a touch sensor metal disposed in contact with the second source-drain electrode pattern, and included in the first touch pad.

10. The display device of claim 9, wherein a material of the first source-drain electrode pattern included in the second touch routing line is different from a material of the second source-drain electrode pattern included in the first touch pad.

11. The display device of claim 9, wherein a thickness of the first source-drain electrode pattern included in the second touch routing line is greater than a thickness of the second source-drain electrode pattern included in the first touch pad.

12. The display device of claim 1, wherein a length of the first touch routing line is smaller than a length of the second touch routing line.

13. The display device of claim 4, wherein the first touch routing line further includes a bending pattern corresponding to a bending area, which is an area between the display area and the first pad area.

14. The display device of claim 13, wherein the bending pattern is in the form of unfilled polygons whose edges are connected in a row or in the form of unfilled circles connected in a row.

15. The display device of claim 4, further comprising:
a planarization layer disposed to cover the second source-drain electrode pattern;
an emission layer disposed on the planarization layer;
an encapsulation layer disposed to cover the emission layer;
a first touch electrode electrically connected to the first touch routing line, and disposed on the encapsulation layer; and
a second touch electrode electrically connected to the first touch routing line, and disposed on the encapsulation layer.

16. The display device of claim 15, further comprising:
a black matrix disposed to overlap with the first touch electrode; and
a color filter disposed to overlap with the emission layer.

17. The display device of claim 1, wherein the first touch routing line and the second touch routing line are disposed alternately in a jumping area between the first pad area and the display area,
wherein the second touch routing line extends in a straight line in a first direction in the jumping area,
wherein the resistance compensation pattern is disposed in a zigzag shape with respect to the first direction in the jumping area.

18. A display device comprising:
a substrate including a display area and a non-display area adjacent to the display area, the non-display area including a first pad area and a second pad area, the first pad area disposed between the second pad area and the display area from a plan view;
a first touch pad disposed in the first pad area;
a second touch pad disposed in the second pad area;
a first touch routing line electrically connected to the first touch pad, the first touch routing line including a meandering shape from a plan view; and
a second touch routing line electrically connected to the second touch pad.

19. The display device of claim 18, wherein the meandering shape of the first touch routing line is configured to increase the resistance value of the first touch routing line such that the difference in resistance values between the first touch routing line and the second touch routing line are reduced.
